(19) United States
(12) Patent Application Publication
(10) Pub. No.: US 2013/0033285 A1
(43) Pub. Date: Feb. 7, 2013

(54) METHODS FOR RELIABILITY TESTING OF SEMICONDUCTOR DEVICES

(71) Applicants: William McMahon, Tuckahoe, NY (US); Andreas Kerber, White Plains, NY (US); Tanya Nigam, Sunnyvale, CA (US); Rudolph Dirk, Dresend (DE)

(72) Inventors: William McMahon, Tuckahoe, NY (US); Andreas Kerber, White Plains, NY (US); Tanya Nigam, Sunnyvale, CA (US); Rudolph Dirk, Dresend (DE)

(73) Assignee: GLOBALFOUNDRIES INC., Grand Cayman (KY)

(21) Appl. No.: 13/196,647

(22) Filed: Aug. 2, 2011

(51) Int. Cl. G01R 31/26

(52) U.S. Cl. 324/762.09

(57) ABSTRACT

In accordance with a exemplary embodiments, methods for performing reliability testing of a plurality of transistors formed on a substrate includes simultaneously stressing the plurality of transistors by applying a voltage potential from each of a plurality of voltage sources to respective drain contacts of a like plurality of row groups and to gate contacts of a like plurality of column groups for a time interval, while applying a reference potential to the substrate and source contacts of the plurality of transistors. After stressing the plurality of transistors for a time interval, the transistors are each measured individually to collect reliability data.

### TECHNICAL FIELD

The technical field generally relates to methods for testing semiconductors, and more particularly, to a method for hot-carrier reliability testing for evaluating the lifetime of a plurality of metal-oxide semiconductor (MOS) transistors in a semiconductor wafer.

### BACKGROUND

Integrated circuits are manufactured by forming hundreds or thousands of semiconductor devices within multitude individual chips formed on a semiconductor wafer. Wafer fabrication requires a high degree of precision, and it is therefore customary to test and characterize the wafer fabrication process and the semiconductor devices produced by that process in order to determine the reliability and failure probability of the semiconductor devices.

Hot-carrier reliability testing is a test procedure for evaluating (estimating) the lifetime of MOS transistors formed in finished products of semiconductor wafers. One conventional method for hot-carrier reliability testing is to individually stress and measure MOS transistors by applying different gate and drain voltages to the device-under-test (DUT) over an extended time interval. Using data collected during the testing and characterizing process, an extrapolation can be made to get a projection of the device lifetime. If the projected lifetime is less than a particular value, (e.g., 10 years or 15 years), the wafer fabrication process must be further refined to avoid producing semiconductor devices overly susceptible to premature failure. Given the number of the drain testing voltages, stress time and measurement time involved, conventional techniques are quite laborious, time-consuming and costly to perform. Moreover, data is collected one device (transistor) at a time, which can result in weeks of delay to approve a wafer fabrication process to manufacture commercially acceptable production semiconductor chips.

Accordingly, a need exists to provide methods for rapidly performing reliability testing of semiconductor device. Additionally it is desirable to provide a MOS transistor hot-carrier injection reliability testing procedure that does not require expensive testing equipment. Still further, it is desirable to provide a MOS transistor hot-carrier reliability testing procedure that rapidly provides device data collection to more quickly characterize a wafer manufacturing process. Furthermore, other desirable features and characteristics of the present invention will become apparent from the subsequent detailed description and the appended claims, taken in conjunction with the accompanying drawings and the foregoing technical field and background.

### BRIEF SUMMARY

In accordance with one embodiment a method for performing reliability testing of a plurality of transistors formed on a substrate includes simultaneously stressing the plurality of transistors by applying a first voltage potential to drain contacts and to gate contacts of first row and column groups of the plurality of transistors, and a second voltage potential to drain contacts and gate contacts of a second row and column groups of the plurality of transistors, while applying a reference potential to the substrate and source contacts of the plurality of transistors. After stressing the plurality of transistors for a time interval, the transistors are each measured individually to collect reliability data.

In accordance with a further embodiment a method for performing reliability testing of an array of transistors formed on a substrate includes simultaneously stressing the array of transistors by applying a voltage potential from each of a plurality of voltage sources to respective drain contacts of a like plurality of row groups and to gate contacts of a like plurality of column groups, while applying a reference potential to the substrate and source contacts of the plurality of transistors. After stressing the plurality of transistors for a time interval, the transistors are each measured individually to collect reliability data.

In accordance with yet another embodiment a method for performing reliability testing for testing a twenty-five pad array of sixty-four transistors formed on a substrate includes coupling two drain contact pads and two gate contact pads to one of four source-measurement units to provide four row groups and four column groups of the array of transistors. Next, the substrate pad and eight source pads of the array of transistors are coupled to a reference potential. The array of sixty-four transistors are simultaneously stressed by applying a voltage potential from each of the source-measurement units to the respective drain and gate pads. After a time interval each one of the four source-measurement units are coupled respectively to one of the substrate pad and a source, gate and drain pad to individually measure data from each transistor in the array of transistors one at a time.

### BRIEF DESCRIPTION OF THE DRAWINGS

The present invention will hereinafter be described in conjunction with the following drawing figures, wherein like numerals denote like elements, and wherein

FIG. 1 is a schematic diagram of a twenty-five pad, sixty-four transistor array for use with exemplary embodiments of the present disclosure;

FIG. 2 is the twenty-five pad, sixty-four transistor array of FIG. 1, illustrating one arrangement for grouping the transistors for testing in accordance with various embodiments;

FIG. 3 is an illustration of an exemplary embodiment of a stress testing configuration;

FIG. 4 is an illustration of an exemplary embodiment for measuring transistors; and

FIG. 5 is a flow diagram of an exemplary method for stressing and measuring transistors.

### DETAILED DESCRIPTION

The following detailed description is merely exemplary in nature and is not intended to limit the invention or the application and uses of the disclosed embodiments. Furthermore, there is no intention to be bound by any expressed or implied theory presented in the preceding technical field, background, brief summary or the following detailed description.

In this document, relational terms such as first and second, and the like may be used solely to distinguish one entity or action from another entity or action without necessarily requiring or implying any actual such relationship or order between such entities or actions. Numerical ordinals such as “first,” “second,” “third,” etc. simply denote different singles of a plurality and do not imply any order or sequence unless specifically defined by the claim language. The sequence of the text in any of the claims does not imply that process steps must be performed in a temporal or logical order according to such sequence unless it is specifically defined by the language of the claim. The process steps may be interchanged in any order without departing from the scope of the disclosed embodiments as long as such an interchange does not contradict the claim language and is not logically nonsensical.

The following description may refer to elements or nodes or features being “connected” or “coupled” together. As used herein, unless expressly stated otherwise, “connected” means that one element/node/feature is directly joined to (or directly communicates with) another element/node/feature, and not necessarily mechanically. Likewise, unless expressly stated otherwise, “coupled” means that one element/node/feature is directly or indirectly joined to (or directly or indirectly communicates with) another element/node/feature, and not necessarily mechanically. Thus, although the schematics depict example arrangements of elements, additional intervening elements, devices, features, modules or components may be present in an embodiment of the disclosure (assuming that the functionality of the system is not adversely affected).

Embodiments of the disclosure may be described herein in terms of functional and/or logical block components and various processing steps. It should be appreciated that such block components may be realized by any number of hardware, software, and/or firmware components configured to perform the specified functions. For example, an embodiment of the disclosure may employ various integrated circuit components, e.g., memory elements, controlled switches, digital signal processing elements, logic elements, look-up tables, or the like, which may carry out a variety of functions under the control of one or more microprocessors or other control devices. In addition, it will be appreciated that embodiments of the disclosure may be practiced in conjunction with any number of testing applications and that the system described herein is merely one example embodiment of the disclosure.

For the sake of brevity, conventional techniques and components related to electrical parts and other functional aspects of the testing system (and the individual operating components of the system) may not be described in detail herein. Furthermore, the connecting lines shown in the various figures contained herein are intended to represent example functional relationships and/or physical couplings between the various elements. It should be noted that many alternative or additional functional relationships or physical connections may be present in an embodiment of the disclosure.

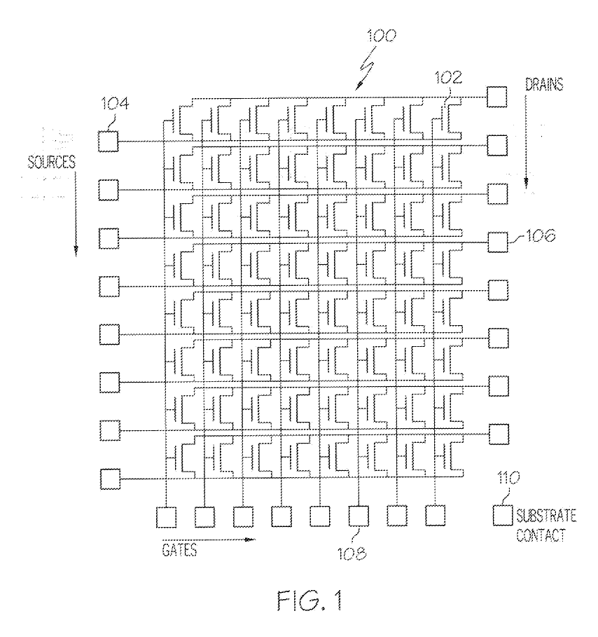

Referring now to FIG. 1, an array 100 of transistors 102 are shown in a conventional twenty-five pad test configuration. While a twenty-five pad, sixty four transitory array is common, it will be appreciated that any size array (e.g., 12×12) may be used in the embodiments of the present disclosure. In the illustrated array 100, sixty-four transistors 102 are arranged with source pads 104 along one side of the array, drain pads 106 along another side of the array, gate pads 108 along yet another side of the array. Together with a substrate pad 110, twenty-five pads are provided for testing the array 100 of transistors 102. In some embodiments, it may be convenient to couple the source contacts of the transistors to a common or fewer pads (i.e., one or more pads) instead of employing a separate pad for each row of transistors as shown. Typically, when testing and characterizing a semiconductor wafer fabrication process, it is customary to run several test vehicles (wafers) through the wafer fabrication process. Accordingly, test patterns (arrays) of transistors and other components are formed using the process under test or development. Following fabrication of the wafer(s), various tests are performed on the transistors and other components. One such test is a hot-carrier injection (HCI) test, which involves stressing the transistors by applying various voltage levels to the drain contacts and gate contacts for an extended time interval (e.g., 10,000 seconds). After the time interval, the transistors are measured for various data values, which are used to predict (estimate) the operational lifetime of transistors formed by the process being evaluated or characterized. In some embodiments, the time interval is divided into sub-intervals (e.g., linear or exponentially increasing sub-intervals) and measurements are taken after each sub-interval for use in statistical analysis to determine (estimate) device lifetime.

According to various embodiments, the transistors 102 of the array 100 are divided into row groups and column groups and simultaneously stressed for the time interval (or sub-intervals). By simultaneously stressing the transistors 102, a significant test time reduction is realized by the disclosed testing method. That is, rather than individually stressing each transistor in the array and thereafter taking individual measurements, simultaneously stressing the array substantially reduces overall test time since the stressing time interval dominates the overall time of completing the total stressing and measuring of the array. After the stress voltages are applied, each transistor 102 is individually measured to collect various data values. Typical HCI data modeling includes gate-voltage, drain-voltage, channel length, channel width and voltage threshold. Additionally, doping (or implant) or other layout dependent mobility modeling and variability characterization may be performed. Since, measurement time for each transistor 102 of the array 100 is less than one second, the entire array 100 can be measured in approximately one minute, which is a negligible time compared to the overall stress time interval (or sub-intervals). Rapid stress/measurement leads to rapid characterization and device lifetime estimation, which can allow a wafer fabrication process to be used for commercial production parts weeks in advance of conventional testing techniques.

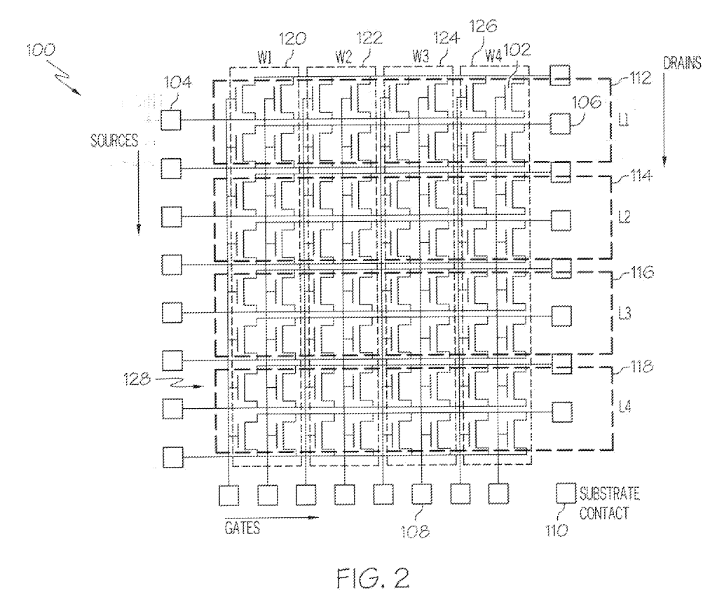

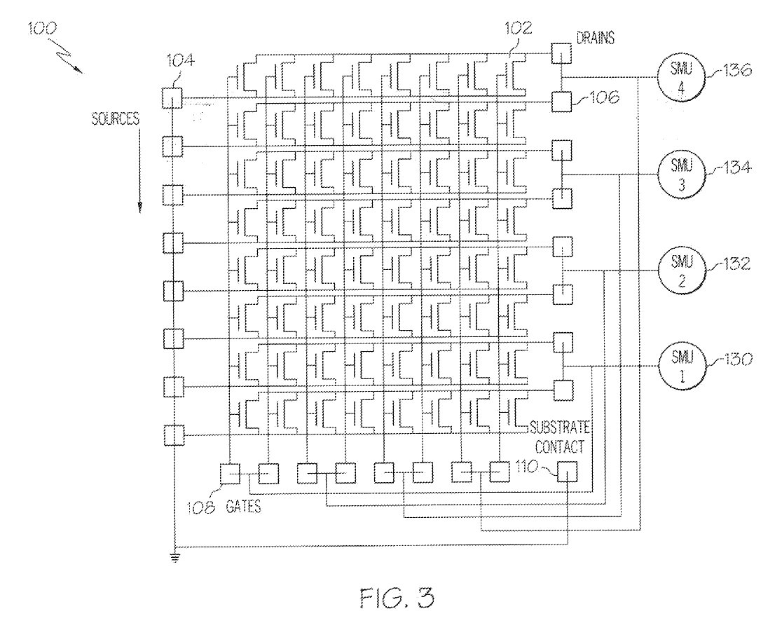

Referring now to FIG. 2, there is shown one embodiment for arranging the transistors 102 of the array 100 into row groups 112-118 and column groups 120-126. Other arrangements are, of course, possible and may be varied by the number of available voltage sources for testing the transistors as will be discussed below in conjunction with FIG. 3. In the illustrated example of FIG. 2, each row group 112-118 and column group 120-126 intersect over a cluster 128 of four transistors. Accordingly, it is convenient to have each transistor of the cluster 128 be of the same size (or channel dimension) so that transistors of various sizes can be tested when evaluating the wafer fabrication process. In some embodiments arrays 100 have transistors 102 all of the same size, while other embodiments use arrays 100 having transistors 102 of different sizes (albeit, the same size within a cluster 128). Still other embodiments will form multiple arrays 100 on the test vehicle (wafer) so that more (and varied) test data is available for evaluating the wafer fabrication process.

Referring now to FIG. 3, an exemplary transistor stress configuration is illustrated showing four source-measurement units (SMUs) 130-136. However, it will be appreciated that any number of SMUs may be used for any particular test. Typically, the number of SMUs employed are those available in the test equipment being employed for the test procedure. The source-measurement units 130-136 are of conventional design and are capable of supplying a voltage potential and measuring current simultaneously. SMUs are commonly included in various types of commercial test equipment, which avoids the capital expenditure of using die stepping equipment and multi-site testers as it common in conventional testing techniques. As shown, each SMU is coupled to two drain pads 106 and two gate pads 108, which implements the row groups 112-118 and column groups 120-126 discussed in FIG. 2. However, it will be appreciated that eight SMUs (or any other number) could be employed to achieve eight row groups and column groups. Moreover, each drain pad 106 and gate pad 108 could have a separate SMU (sixteen in this example) if desired.

During stress application, the source pads 106 and substrate contact 110 are coupled to a reference potential (e.g., ground) in one embodiment. However, in other embodiments, a different reference potential could be used if another SMU was available. These embodiments have the advantage of being able to measure substrate current during the stress procedure if such information is helpful in characterizing the wafer fabrication process. With the four SMUs 130-136 arranged as shown, sixteen voltage combinations are simultaneously applied to the array 100. For example, SMU 1 (130) may apply a voltage potential of 1.0 volts to row group 118 and column group 120. SMU 2 (132) may apply 1.2 volts, while SMU 3 (134) applies 1.4 volts and SMU 4 (136) applies 1.6 volts. Other voltage potentials are possible, however, stressing the transistors 102 at voltage potentials close to actual transistor operation voltages is advantageous as it provides data more closely aligned to actual operating conditions. The stress voltages are applied for a time interval (e.g., 10,000 seconds) after which time the transistors 102 are each individually measured to collect data values. Alternately, the time interval may be divided into sub-intervals to apply one or more stress intervals and measurements taken after each sub-interval has elapsed. In one embodiment, the sub-intervals are linear (e.g., 1,000 seconds), while other embodiments may utilize exponentially increasing sub-intervals (e.g., increasing ten measurement cycles per decade of time) over the total stress time interval.

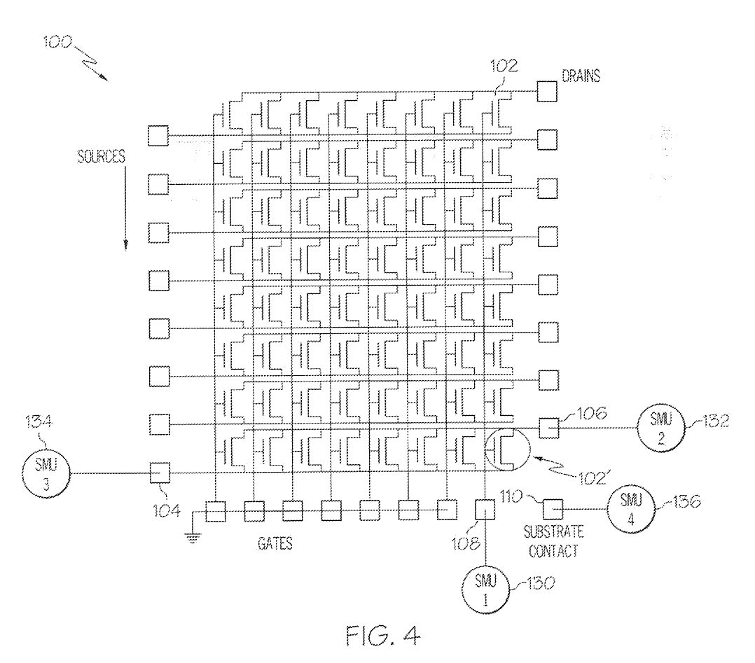

To take measurements, the SMUs 130-136 are re-configured as illustrated in FIG. 4. SMU reconfiguration may be accomplished via a switching arrangement or matrix (not shown) to achieve the illustrated configuration. As previously mentioned, the array 100 is simultaneously stressed, however, measurements are made on each transistor 102 individually. As can be seen in FIG. 4, SMU 1 (130) is coupled to a gate pad 108, while SMU 2 (132) is coupled to a drain pad 106 and SMU 3 (134) is coupled to a source pad 104. SMU 4 (136) is coupled to the substrate pad 110. This activates one transistor 102′, which is then measured by the SMUs for various data values. Typically, during the measurement, the gates of the non-measured transistors are coupled to ground by the switching arrangement or could be slightly negatively biased if an additional SMU were available to supply the bias potential. The SMUs continue to be reconfigured (switched) until each transistor 102 has been individually measured. If sub-intervals are used, the SMUs would be reconfigured again as shown in FIG. 3 for another stress application. After all data is collected, it is processed via statistical analysis to provide information leading to a predication (estimation) of device lifetime.

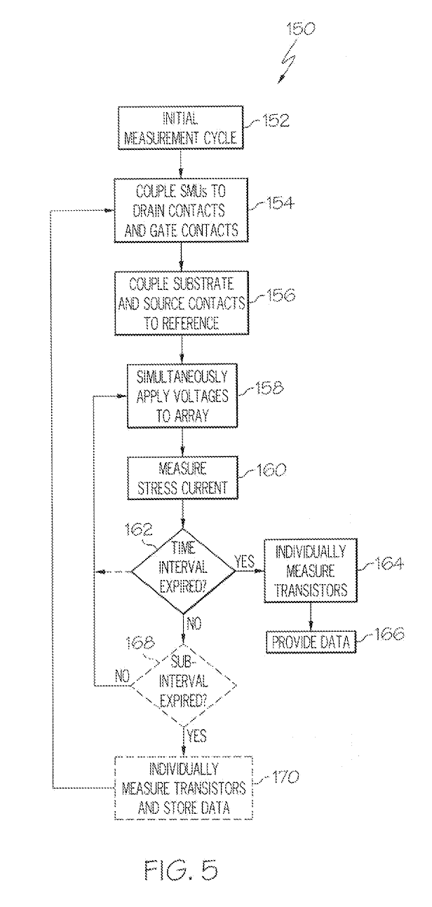

Referring now to FIG. 5, there is shown a flow diagram 150 illustrating an exemplary methodology for HCI testing according to the present disclosure. The routine begins in step 152 where an initial measurement cycle is performed (see, FIG. 4) to obtain the pre-stress initial conditions of the transistors 102. Next, the SMUs are coupled (step 154) to the drain contacts and gate contacts (see FIG. 3) to implement the row groups and column groups (see FIG. 2) selected for stressing. In step 156, the source contacts and substrate contact are coupled to a reference potential (e.g., ground). Step 158 simultaneously stresses the array by applying voltage potentials to the transistors of the array. During this time, it may be convenient or useful to measure stress current(s) (step 160) during the array stress time. Decision 162 determines whether the time interval (e.g., 10,000 seconds) has expired, if so, step 164 reconfigures the SMUs and individually measures each transistor in the array (see FIG. 4) to collect data useful for estimating device lifetime that is provided for statistical processing in step 166. Conversely, if the determination of decision 162 is that the time interval has not expired, the routine may optionally determine (decision 168) whether a sub-interval (e.g., linear or exponential) has expired. If so, the SMUs are reconfigured (see, FIG. 4) and the transistors of the array are individually measured and the data is stored pending completion of the full stress test time interval. After measurement, the SMUs are again reconfigured to the stress configuration (see, FIG. 3) by returning to step 154. Conversely, if the determination of decision 168 (or in decision 162 if sub-intervals are not used) is that the sub-interval has not expired, the routine loops back to step 158 where the SMUs continue to simultaneously apply voltage potentials and stress the array.

According to various embodiments, different measurement types can be implemented. For example, simultaneously applying different voltage levels during array stress provides data useful to determining gate-voltage and drain-voltage modeling. A simultaneous application of the same voltage potential to same size transistors generates data useful for large statistics. Also simultaneous application of the same voltage potential to transistors of different sizes or layouts generates data useful for determining impact of on drain current degradation based upon channel width, impact of on drain current degradation based upon channel length, voltage threshold, doping or implant or other layout dependent mobility modeling and variability characterization.

While at least one exemplary embodiment has been presented in the foregoing detailed description, it should be appreciated that a vast number of variations exist. It should also be appreciated that the exemplary embodiments are only examples, and are not intended to limit the scope, applicability, or configuration of the invention in any way. Rather, the foregoing detailed description will provide those skilled in the art with a convenient road map for implementing the exemplary embodiments. It should be understood that various changes can be made in the size, spacing and doping of elements without departing from the scope of the invention as set forth in the appended claims and the legal equivalents thereof.

What is claimed is:

1. A method for testing a plurality of transistors formed on a substrate, comprising:
applying a reference potential to the substrate and source contacts of the plurality of transistors;
simultaneously applying a first voltage potential to drain contacts and to gate contacts of a first row group and a first column groups of the plurality of transistors, and a second voltage potential to drain contacts and gate contacts of a second row group and a second column group of the plurality of transistors, for a time interval; and
individually measuring data from the plurality of transistors after the time interval.

2. The method of claim 1 for testing a plurality of transistors formed on a substrate, further comprising measuring a stress current provided to the first row and column groups and the second row and column groups of the plurality of transistors during the time interval.

3. The method of claim 1 for testing a plurality of transistors formed on a substrate, further comprising:
simultaneously applying the first voltage potential to the drain contacts and the gate contacts of the first row and column groups of the plurality of transistors, and the second voltage potential to the drain contacts and the gate contacts of the second row and column groups of the plurality of transistors, for a second time interval; and
individually measuring data from the plurality of transistors after the second time interval.

4. The method of claim 3 for testing a plurality of transistors formed on a substrate, further comprising measuring a stress current provided to the first row and column groups and the second row and column groups of the plurality of transistors during the second time interval.

5. The method of claim 1 for testing a plurality of transistors formed on a substrate, further comprising simultaneously applying the first voltage source to the drain contacts and to the gate contacts of the first row and column groups of the plurality of transistors each having a first transistor size.

6. The method of claim 5 for testing a plurality of transistors formed on a substrate, further comprising simultaneously applying the second voltage source to the drain contacts and to the gate contacts of the second row and column groups of the plurality of transistors each having a second transistor size.

7. The method of claim 1 for testing a plurality of transistors formed on a substrate, further comprising measuring data values individually for each of the plurality of transistors, the data values comprising at least one of the follow group of data values: gate voltage, drain voltage, impact of on drain current degradation based upon channel width, impact of on drain current degradation based upon channel length, voltage threshold, doping or layout mobility variation.

8. The method of claim 1 for testing a plurality of transistors formed on a substrate, further comprising:
simultaneously applying a third voltage potential to drain contacts and to gate contacts of a third row and column groups of the plurality of transistors, and a fourth voltage potential to drain contacts and to gate contacts of a fourth row and column groups of the plurality of transistors, for a time interval; and
individually measuring data from the plurality of transistors after the time interval.

9. The method of claim 8 for testing a plurality of transistors formed on a substrate, further comprising measuring a stress current provided to the third and the fourth row and column groups of the plurality of transistors during the time interval.

10. A method for testing an array of transistors formed on a substrate, comprising:
simultaneously applying, for a time interval, a voltage potential from each of a plurality of voltage sources to respective drain contacts of a like plurality of row groups and to respective gate contacts of a like plurality of column groups of the array of transistors, while applying a reference potential to the substrate and source contacts of the array of transistors; and
individually measuring data from each transistor in the array of transistors after the time interval.

11. The method of claim 10 for testing an array of transistors formed on a substrate, further comprising measuring a stress current provided to each of the like plurality of row and column groups during the time interval.

12. The method of claim 10 for testing an array of transistors formed on a substrate, further comprising repeating the simultaneously applying for a second time interval and individually measuring data from each transistor in the array of transistors after the second time interval.

13. The method of claim 10 for testing an array of transistors formed on a substrate, further comprising applying a different voltage potential for each of the plurality of voltage sources, each voltage potential being one from the following group of voltage potentials: 1.0 volts, 1.2 volts, 1.4 volts and 1.6 volts.

14. The method of claim 10 for testing an array of transistors formed on a substrate, further comprising coupling a respective source-measurement unit to each of the substrate and a gate, source and drain contact of each transistor in the array of transistors to take measurements one transistor at a time.

15. The method of claim 10 for testing an array of transistors formed on a substrate, further comprising the time interval being divided into time sub-intervals and the simultaneously applying and the individually measuring is repeated for each of the time sub-intervals.

16. The method of claim 10 wherein the data is processed via a statistical analysis processor to provide reliability information for the transistors in the array of transistors.

17. The method of claim 10 for testing an array of transistors formed on a substrate, further comprising simultaneously applying a different voltage potential and the data is processed to provide gate-voltage and drain-voltage reliability information for the transistors in the array of transistors.

18. The method of claim 10 for testing an array of transistors formed on a substrate, including the array of transistors being of a common transistor size, and further comprising simultaneously applying a same voltage potential and the data is processed to provide reliability information for the array of transistors.

19. The method of claim 10 for testing an array of transistors formed on a substrate, including the array of transistor having different transistor sizes and further comprising simultaneously applying a same voltage potential and the data is processed to provide impact of on drain current degradation based upon channel width, impact of on drain current degradation based upon channel length, voltage threshold, doping or layout mobility variation reliability information for the transistors of the array of transistors.

20. A method for testing a twenty-five pad array of sixty-four transistors formed on a substrate, comprising:
coupling two drain contact pads and two gate contact pads to one of four source-measurement units to provide four row groups and four column groups of the array of transistors;
coupling a substrate pad and eight source pads of the array of transistors to a reference potential;
simultaneously applying a voltage potential from each of the source-measurement units to the respective drain and gate pads for a time interval; and
coupling, after the time interval, one of the four source-measurement units respectively to one of the substrate pad and a source, gate and drain pad to individually measure data from each transistor in the array of transistors.
